(19) United States
(12) Patent Application Publication
(10) Pub. No.: US 2026/0218374 A1
(43) Pub. Date: Jul. 30, 2026

(54) FILM FORMING METHOD AND SEMICONDUCTOR MANUFACTURING APPARATUS

(71) Applicant: Tokyo Electron Limited, Tokyo (JP)

(72) Inventors: Yusuke IGUCHI, Nirasaki-shi (JP); Kensaku NARUSHIMA, Nirasaki-shi (JP); Takashi KOBAYASHI, Nirasaki-shi (JP); Takashi SAKUMA, Nirasaki-shi (JP)

(21) Appl. No.: 19/573,121

(22) Filed: Mar. 20, 2026

Related U.S. Application Data
(63) Continuation of application No. PCT/JP2024/029627, filed on Aug. 21, 2024.

(30) Foreign Application Priority Data
Oct. 2, 2023 (JP) 2023-171278

(51) Int. Cl. C23C 16/04; C23C 16/02; C23C 16/14; C23C 16/455; C23C 16/505; C23C 16/56; H10P 70/00; H10W 20/00

(52) U.S. Cl. CPC C23C 16/045; C23C 16/0227; C23C 16/14; C23C 16/45536; C23C 16/45544; C23C 16/45553; C23C 16/505; C23C 16/56; H10P 70/27; H10W 20/035

(57) ABSTRACT

A film forming method of forming a metal wiring on a silicon-based substrate to be processed, by forming a contact made of a metal silicide at a bottom portion of a pattern as an opening in an insulating film of the substrate while forming a metal film inside the pattern, includes: a first film formation process of forming a first metal film inside the pattern; a film thickness adjustment process of adjusting a film thickness of the formed first metal film; and a second film formation process of forming a second metal film on the first metal film by using a raw material gas, wherein in the film thickness adjustment process, the formed first metal film is etched by using the raw material gas.

### CROSS-REFERENCE TO RELATED APPLICATION

The application is a Bypass Continuation Application of PCT International Application No. PCT/JP2024/029627, filed on Aug. 21, 2024 and designating the United States, the international application being based upon and claiming the benefit of priority from Japanese Patent Application No. 2023-171278, filed on Oct. 2, 2023, the entire contents of which are incorporated herein by reference.

### TECHNICAL FIELD

The present disclosure relates to a film forming method and a semiconductor manufacturing apparatus.

### BACKGROUND

For example, in a logic integrated circuit (IC) as a semiconductor device, titanium (Ti) is used as a contact material of a source and a drain. Titanium is deposited on an inner wall or a bottom surface of a trench or a contact hole, which is a pattern formed in an insulating film (see, for example, Patent Document 1). Thereafter, a low-resistance metal, for example, ruthenium (Ru), is embedded in the pattern as a wiring material.

### PRIOR ART DOCUMENT

### [Patent Document]

Patent Document 1: Japanese Patent Laid-Open Publication No. 2012-204522

### SUMMARY

A film forming method according to one embodiment of the present disclosure is a film forming method of forming a metal wiring on a silicon-based substrate to be processed, by forming a contact made of a metal silicide at a bottom portion of a pattern as an opening in an insulating film of the substrate while forming a metal film inside the pattern, and includes: a first film formation process of forming a first metal film inside the pattern; a film thickness adjustment process of adjusting a film thickness of the formed first metal film; and a second film formation process of forming a second metal film on the first metal film by using a raw material gas, wherein in the film thickness adjustment process, the formed first metal film is etched by using the raw material gas

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view for explaining an exemplary configuration of a semiconductor manufacturing apparatus according to an embodiment of a technique of the present disclosure.

FIG. 2 is a partially enlarged cross-sectional view showing an example of a vicinity of a pattern in a wafer with a wiring material embedded therein after various processes are performed in the semiconductor manufacturing apparatus of FIG. 1.

FIG. 3 is a flowchart (example) for explaining a film forming method according to the embodiment.

FIGS. 4A to 4E are process diagrams (examples) for explaining the film forming method according to the embodiment.

FIG. 5 is a flowchart (example) for explaining a modification of the film forming method according to the embodiment.

FIGS. 6A to 6F are process diagrams (examples) for explaining the modification of the film forming method according to the embodiment.

FIG. 7 is a plan view for explaining a configuration of a modification of the semiconductor manufacturing apparatus according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In recent years, zirconium (Zr) is considered as a promising contact material, and when Zr is used, Zr is stacked on an inner wall or a bottom surface of a pattern, together with Ti. However, there is a concern that when a Zr film is thickened inside the pattern, a volume of a wiring material inside the pattern is consequently reduced, resulting in an increase in a wiring resistance.

In this regard, a technique according to the present disclosure includes forming a Zr film inside a pattern and then etching the Zr film to adjust a thickness of the Zr film.

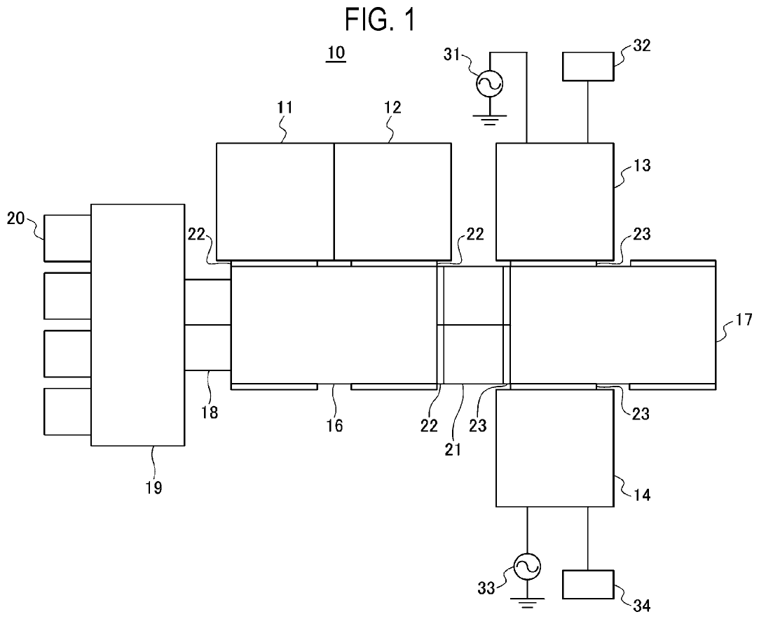

Hereinafter, an embodiment of the technique of the present disclosure will be described with reference to the drawings. FIG. 1 is a plan view for explaining an exemplary configuration of a semiconductor manufacturing apparatus according to the embodiment.

In FIG. 1, a semiconductor manufacturing apparatus 10 includes a chemical oxide removal (COR) chamber 11 that performs a COR process and a post heat treatment (PHT) chamber 12 that performs a PHT process. The semiconductor manufacturing apparatus 10 further includes a Zr film formation chamber 13 (a first film former) that performs a Zr film formation process and a Ti film formation chamber 14 (a second film former) that performs a Ti film formation process.

The COR chamber 11 and the PHT chamber 12 are connected to a first transfer module 16, and the Zr film formation chamber 13 and the Ti film formation chamber 14 are connected to a second transfer module 17. Further, the first transfer module 16 is connected to a loader module 19 via a load lock module 18. In addition, an arrangement of the modules is not limited to the above configuration. The COR chamber 11 and the PHT chamber 12 may be connected to the second transfer module 17, or the Zr film formation chamber 13 and the Ti film formation chamber 14 may be connected to the first transfer module 16.

The loader module 19 is provided with a plurality of load ports 20, and each load port 20 is provided with a container, for example, a front opening unified pod (FOUP) (not shown), that accommodates a plurality of wafers. In addition, the first transfer module 16 and the second transfer module 17 are connected to each other via a wafer deliverer 21.

In the semiconductor manufacturing apparatus 10, each of the loader module 19, the first transfer module 16, and the second transfer module 17 incorporates a transfer robot (not shown). Each transfer robot transfers a wafer among the COR chamber 11, the PHT chamber 12, the Zr film formation chamber 13, the Ti film formation chamber 14, and the load ports 20.

The loader module 19 is an atmospheric transfer system or a nitrogen transfer system, and an interior thereof is maintained at atmospheric pressure. The first transfer module 16 and the second transfer module 17 are vacuum transfer systems, and interiors thereof are depressurized to a near-vacuum state. The load lock module 18 is configured such that an interior thereof is switchable between atmospheric pressure and the near-vacuum state. When a wafer is transferred between the first transfer module 16 and the loader module 19, by switching an internal pressure of the load lock module 18, the wafer transfer is implemented without changing an internal pressure of the first transfer module 16 or the loader module 19.

In addition, the COR chamber 11, the PHT chamber 12, and the wafer deliverer 21 are connected to the first transfer module 16 via gate valves 22. Further, the Zr film formation chamber 13, the Ti film formation chamber 14, and the wafer deliverer 21 are connected to the second transfer module 17 via gate valves 23.

In the semiconductor manufacturing apparatus 10, a silicon-based wafer transferred from the load port 20 is first transferred sequentially to the COR chamber 11 and the PHT chamber 12, and a native oxide film formed on a surface of silicon (Si) or silicon germanium (SiGe), which is a constituent material of the wafer, is removed by the COR process and the PHT process. Subsequently, the wafer is transferred to the Zr film formation chamber 13, and a Zr film is formed inside a pattern, which is an opening such as a trench (including a via hole) or a contact hole formed in an insulating film, by the Zr film formation process. Thereafter, the wafer is transferred to the Ti film formation chamber 14, and a Ti film is formed on the Zr film inside the pattern by the Ti film formation process. Further, a surface of the Ti film is nitrided by a nitridation process, and then the wafer is accommodated in the FOUP of the load port 20 via the second transfer module 17, the first transfer module 16, and the loader module 19. Subsequently, a metal film formation process is performed on the wafer in another film formation apparatus, and a wiring metal, for example, ruthenium (Ru), molybdenum (Mo), or tungsten (W), is embedded inside the pattern. Further, the metal film formation process may be performed without nitriding the surface of the Ti film, or a separate chamber for performing the nitridation process therein may be prepared to facilitate the nitridation process. In addition, a chamber for performing the metal film formation process may be provided in the semiconductor manufacturing apparatus 10.

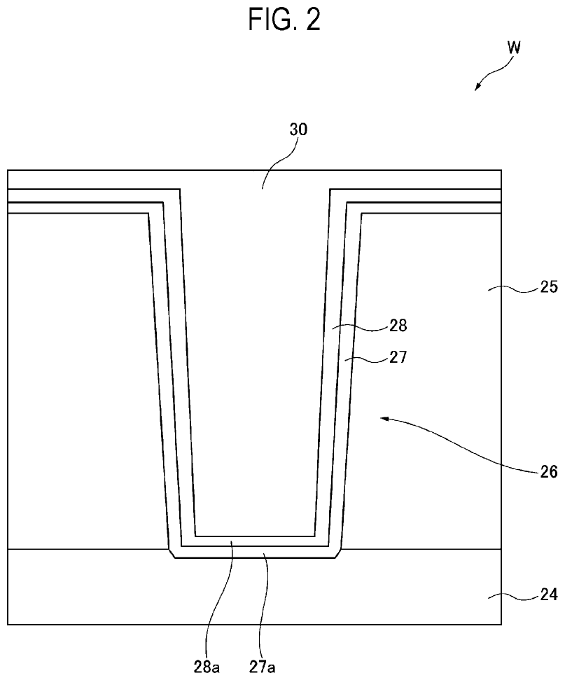

FIG. 2 is a partially enlarged cross-sectional view showing an example of a vicinity of a pattern in a wafer with a wiring material embedded therein after various processes are performed in the semiconductor manufacturing apparatus 10 of FIG. 1. In FIG. 2, a wafer (substrate to be processed) W includes a base 24 made of Si or SiGe, and an insulating film 25 made of, for example, silicon nitride (SiN) is formed on the base 24. A contact hole or a trench as a pattern 26 is formed as an opening in the insulating film 25, and the base 24 is exposed from a bottom of the pattern 26.

The bottom and a sidewall of the pattern 26 and an upper surface of the insulating film 25 are covered with a Zr film 27 (a first metal film), and a surface of the Zr film 27 is covered with a Ti film 28 (a second metal film). Further, an inside of the pattern 26 is filled with a wiring metal 30. At this time, a surface of the Ti film 28 may be modified into titanium nitride (TiN) by the nitridation process to form a barrier layer. The barrier layer suppresses metal molecules of the wiring metal 30 from entering and diffusing into the insulating film 25. In addition, a part of the Zr film 27 may also be modified into zirconium nitride (ZrN) to form a thin barrier layer (not shown), and the thin barrier layer also suppresses the metal molecules from entering and diffusing into the insulating film 25.

Further, the Zr film 27 and the Ti film 28 at a bottom portion of the pattern 26 are silicided by contact with the base 24, and are respectively modified into a zirconium silicide (ZrSi) 27a and a titanium silicide (TiSi) 28a, which are metal silicides. The ZrSi 27a and the TiSi 28a function as a contact between the base 24 and the wiring metal 30.

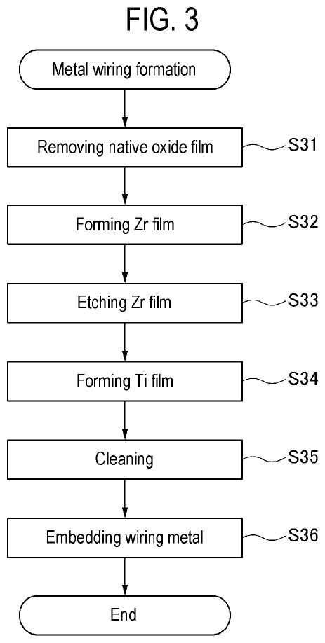

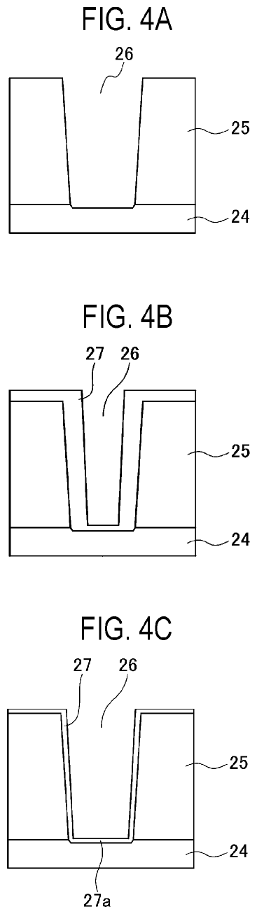

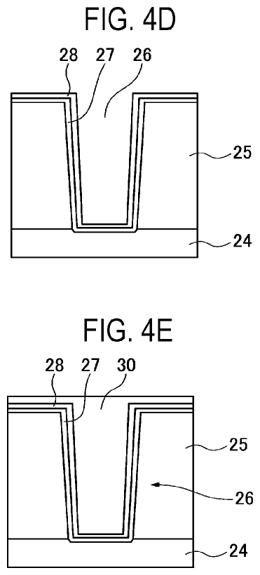

FIG. 3 is a flowchart (example) for explaining a film forming method according to the present embodiment, and FIGS. 4A to 4E are process diagrams (examples) for explaining the film forming method according to the present embodiment.

In a metal wiring formation method as the film forming method according to the present embodiment, in the semiconductor manufacturing apparatus 10, the wafer W is first transferred from the FOUP provided in the load port 20 to the COR chamber 11. At this time, the wafer W has the insulating film 25 formed on the base 24, and the pattern 26 is open in the insulating film 25 (see FIG. 4A).

In the COR chamber 11, the COR process is performed on the wafer W to modify a native oxide film formed on a surface of the base 24 made of Si or SiGe into ammonium hexafluorosilicate ((NH₄)₂SiF₆). Thereafter, the wafer W is transferred to the PHT chamber 12, and in the PHT chamber 12, the PHT process is performed on the wafer W to sublimate the ammonium hexafluorosilicate. Therefore, the native oxide film is removed (step S31) (an oxide film removal process).

Subsequently, the wafer W is transferred to the Zr film formation chamber 13. The Zr film formation chamber 13 is, for example, a plasma enhanced chemical vapor deposition (PECVD) apparatus, and includes a radio-frequency power supply 31 and a film formation gas source 32. In the Zr film formation chamber 13, a radio-frequency voltage applied from the radio-frequency power supply 31 forms an electric field inside the Zr film formation chamber 13, and the film formation gas source 32 supplies a film formation gas containing Zr into the Zr film formation chamber 13. At this time, Zr plasma is generated from the film formation gas, and ions or radicals of the Zr plasma adhere to a surface of the wafer W to form the Zr film 27 inside the pattern 26 (see FIG. 4B) (step S32) (a first film formation process).

Subsequently, the wafer W is transferred to the Ti film formation chamber 14. The Ti film formation chamber 14 is also, for example, a PECVD apparatus, and includes a radio-frequency power supply 33 and a raw material gas source 34 (an introducer of a raw material gas). Here, the raw material gas source 34 supplies titanium tetrachloride (TiCl₄) gas as the raw material gas into the Ti film formation chamber 14. The TiCl₄ gas reacts with the Zr film 27 to generate a zirconium chloride. Specifically, according to a reaction equation shown in Equation (1) below, the TiCl₄ gas reacts with Zr to generate a zirconium chloride (ZrClₓ) and a titanium chloride (TiCl_{y}). Further, in Equation (1) below, x is 3 or 4, and y is any one of 2 to 4.

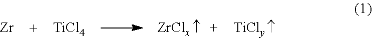

In the Ti film formation chamber 14, since the wafer W is heated by a heater of a stage (not shown), ZrClₓ and TiCl_{y} sublimate and scatter. Thus, the Zr film 27 is etched, and a film thickness of the Zr film 27 is adjusted (see FIG. 4C) (step S33) (a film thickness adjustment process). When the Zr film 27 is etched, the radio-frequency power supply 33 does not apply a radio-frequency voltage into the Ti film formation chamber 14, and therefore the Zr film 27 is exposed to the TiCl₄ gas that is not plasmarized. Alternatively, the Zr film 27 may be etched by plasmarizing the TiCl₄ gas to generate TiCl₄ plasma and facilitate the reaction of Equation (1).

A duration of etching the Zr film 27 is set according to a required film thickness (amount) of the Zr film 27 remaining inside the pattern 26. For example, a time required for etching the Zr film 27 by the TiCl₄ gas to a desired remaining film thickness is measured in advance, and the duration for etching the Zr film 27 is set based on the measured time.

In addition, in step S33, the Zr film 27 at the bottom portion of the pattern 26 has been modified into the ZrSi 27a, and thus is hardly etched with the TiCl₄ gas. Therefore, in step S33, the Zr film 27 formed on the sidewall of the pattern 26 is mainly etched.

In addition, the raw material gas for use in etching the Zr film 27 is not limited to the TiCl₄ gas. For example, at least one gas of tungsten pentachloride (WCl₅) gas, tungsten hexachloride (WCl₆) gas, molybdenum pentachloride (MoCl₅) gas, molybdenum hexachloride (MoCl₆) gas, hafnium tetrachloride (HfCl₄) gas, or zirconium tetrachloride (ZrCl₄) gas may be used as the raw material gas. Alternatively, a mixed gas of at least one of the gases described above and the TiCl₄ gas may be used as the raw material gas. The metal chloride gases described above also react with the Zr film 27 and generate zirconium chlorides.

After etching the Zr film 27, in the Ti film formation chamber 14, the radio-frequency voltage applied from the radio-frequency power supply 33 forms an electric field inside the Ti film formation chamber 14, and the raw material gas source 34 supplies the TiCl₄ gas into the Ti film formation chamber 14. At this time, the TiCl₄ gas is plasmarized to generate Ti plasma, and ions or radicals of the Ti plasma adhere to the surface of the residual Zr film 27 to form the Ti film 28 inside the pattern 26 (see FIG. 4D) (step S34) (a second film formation process). Further, at this time, hydrogen (H₂) gas is introduced into the Ti film formation chamber 14 as a reducing gas. The hydrogen gas facilitates formation of the Ti film 28 by removing Cl atoms from a TiCl-based precursor, which is generated by plasmarization of the TiCl₄ gas, by reduction and causing Ti atoms to remain on the surface of the Zr film 27.

Here, since the TiCl₄ gas etches a portion of the formed Ti film 28, it is possible to suppress a film thickness of the Ti film 28 from increasing unnecessarily. The etching of the Ti film 28 is performed by generating a new titanium chloride by reaction of the TiCl₄ gas with the Ti film 28 and sublimating the newly generated titanium chloride.

On the sidewall of the pattern 26, a total film thickness of the Zr film 27 and the Ti film 28 after execution of step S34 becomes smaller than a film thickness of the Zr film 27 after execution of step S32. Further, the raw material gas for use in forming the Ti film 28 is not limited to the TiCl₄ gas, and may be a Ti-containing chloride gas other than TiCl₄ or a Ti-containing halide gas, for example.

After forming the Ti film 28, the wafer W is cleaned in the Ti film formation chamber 14 (step S35) (a cleaning process). In the cleaning process, etching residues of Zr are removed from the surface of the wafer W by sputtering using plasma generated from argon gas or hydrogen gas, and the etching residues are discharged to an outside of the Ti film formation chamber 14 by an exhaust device (not shown).

Thereafter, a metal film formation process is performed on the wafer W to embed the wiring metal 30 inside the pattern 26 (see FIG. 4E) (step S36) (a wiring process).

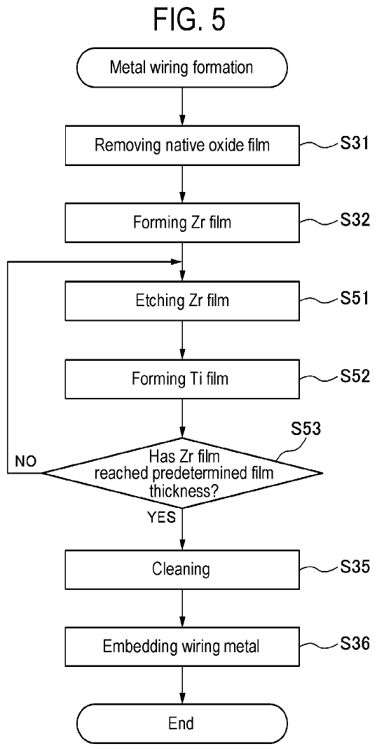

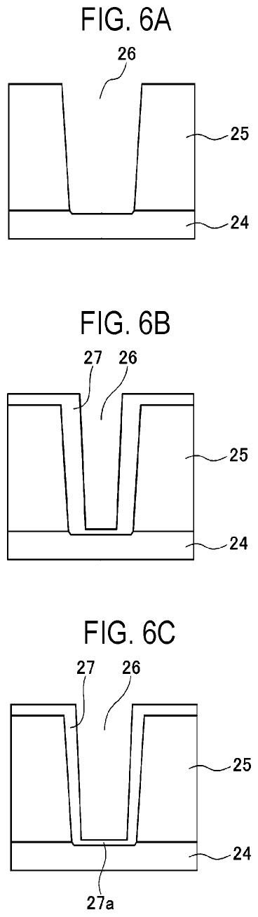

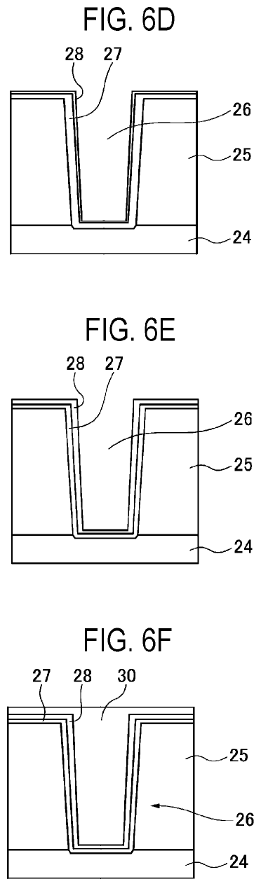

FIG. 5 is a flowchart (example) for explaining a modification of the film forming method according to the present embodiment, and FIGS. 6A to 6F are process diagrams (examples) for explaining the modification of the film forming method according to the present embodiment.

A metal wiring formation method shown in FIGS. 5 and 6A to 6F differs from the metal wiring formation method shown in FIGS. 3 and 4A to 4E in that etching of the Zr film 27 and formation of the Ti film 28 are repeated, but other steps are the same as in the metal wiring formation method shown in FIGS. 3 and 4A to 4E. Therefore, hereinafter, detailed descriptions of steps that are the same as those of the metal wiring formation method shown in FIGS. 3 and 4A to 4E will be omitted.

In the metal wiring formation method as the modification of the film forming method according to the present embodiment, first, the native oxide film on the wafer W is removed (see FIG. 6A) (step S31). Subsequently, the Zr film formation process is performed on the wafer W to form the Zr film 27 inside the pattern 26 (see FIG. 6B) (step S32).

Subsequently, the wafer W is transferred to the Ti film formation chamber 14. In the Ti film formation chamber 14, first, by exposing the Zr film 27 to the TiCl₄ gas, the Zr film 27 is etched (step S51). Since an execution time of step S51 is set to be shorter than an execution time of step S33, a remaining amount of the Zr film 27 after a first execution of step S51 is larger than a remaining amount of the Zr film 27 after execution of step S33 (see FIG. 6C).

After etching the Zr film 27, in the Ti film formation chamber 14, Ti plasma is generated from the TiCl₄ gas, and the Ti film 28 is formed on the surface of the Zr film 27 inside the pattern 26 (step S52). Since an execution time of step S52 is set to be shorter than an execution time of step S34, a film thickness of the Ti film 28 after a first execution of step S52 is smaller than a film thickness of the Ti film 28 after execution of step S34 (see FIG. 6D).

Thereafter, it is determined whether the Zr film 27 has reached a predetermined remaining film thickness (whether the Zr film 27 has been thinned to the predetermined remaining film thickness) (step S53). For example, the remaining film thickness of the Zr film 27 may be estimated or observed by a means for estimating a remaining film thickness or the Zr film 27 or a means for observing a remaining film thickness of the Zr film 27, which is provided in the Ti film formation chamber 14. In this case, the determination of step S53 is performed based on the estimated or observed remaining film thickness of the Zr film 27.

When the Zr film 27 has not reached the predetermined remaining film thickness (“NO” in step S53), the process returns to step S51 to repeat the etching of the Zr film 27 and the formation of the Ti film 28. Therefore, when the Ti film 28 is stacked on the Zr film 27, the film thickness of the Ti film 28 increases as the film thickness of the Zr film 27 decreases. Repeating the etching of the Zr film 27 and the formation of the Ti film 28 is implemented by applying a pulsed radio-frequency voltage from the radio-frequency power supply 33 into the Ti film formation chamber 14. That is, the Zr film 27 is etched when the radio-frequency voltage is not applied, and the Ti film 28 is formed by the Ti plasma generated from the TiCl₄ gas when the radio-frequency voltage is applied. In addition, an etching amount of the Zr film 27 by a single execution of step S51 and a formation amount of the Ti film 28 by a single execution of step S52 are controlled by adjusting a duty ratio of the pulse application of the radio-frequency voltage.

On the other hand, when the Zr film 27 has reached the predetermined remaining film thickness (“YES” in step S53), the etching of the Zr film 27 and the formation of the Ti film 28 are stopped, and the process proceeds to step S35. Alternatively, after the Zr film 27 has reached the predetermined remaining film thickness, step S52 may be executed to further increase the film thickness of the Ti film 28.

In step S53, it may also be determined whether a repetition number of steps S51 and S52 has reached a predetermined number. In this case, a required repetition number of steps S51 and S52 for etching the Zr film 27 by the TiCl₄ gas to a desired remaining film thickness is measured in advance, and the measured repetition number is set as the predetermined number. In addition, a total film thickness of the Zr film 27 and the Ti film 28 after execution of step S53 becomes smaller than the film thickness of the Zr film 27 after execution of step S32 (see FIG. 6E).

Thereafter, the cleaning process is performed on the wafer W (step S35), and the metal film formation process is performed to embed the wiring metal 30 inside the pattern 26 (see FIG. 6F) (step S36).

According to the present embodiment, since the Zr film 27 formed inside the pattern 26 of the wafer W is etched, it is possible to prevent reduction in the volume of the wiring metal 30 embedded inside the pattern 26. Therefore, it is possible to suppress an increase in wiring resistance of the wiring metal 30.

Further, in the present embodiment, the etching of the Zr film 27 and the formation of the Ti film 28 are performed by using the same TiCl₄ gas. Therefore, it is possible to reduce types of gases used in the semiconductor manufacturing apparatus 10. In addition, by using the same TiCl₄ gas, the etching of the Zr film 27 and the formation of the Ti film 28 can be performed in the same Ti film formation chamber 14, and thus it is possible to reduce the number of chambers and to prevent an increase in a footprint of the semiconductor manufacturing apparatus 10. Further, since it is not necessary to transfer the wafer W to another chamber between the etching of the Zr film 27 and the formation of the Ti film 28, it is also possible to improve throughput.

In addition, in the present embodiment, the Zr film formation chamber 13, the Ti film formation chamber 14, and a nitridation chamber (when provided separately from the Ti film formation chamber 14) are connected to the same second transfer module 17. Therefore, the formation of the Zr film 27, the etching of the Zr film 27, the formation of the Ti film 28, and the formation of a barrier layer can be performed in-situ within a same vacuum system. Therefore, it is possible to improve throughput. In addition, since the cleaning process is performed on the wafer W in the Ti film formation chamber 14, it is possible to suppress the etching residues of Zr from entering the nitridation chamber connected to the same vacuum transfer system.

Further, although the Ti film 28 is formed on the Zr film 27 in the present embodiment, an electrical resistance is reduced when Ti is stacked on Zr. Therefore, an ohmic contact resistance can be reduced particularly at the contact where TiSi 28a is stacked on the ZrSi 27a.

While the exemplary embodiments of the present disclosure have been described above, the present disclosure is not limited to the above-described embodiments, and various modifications and variations may be made within the scope of the gist of the present disclosure.

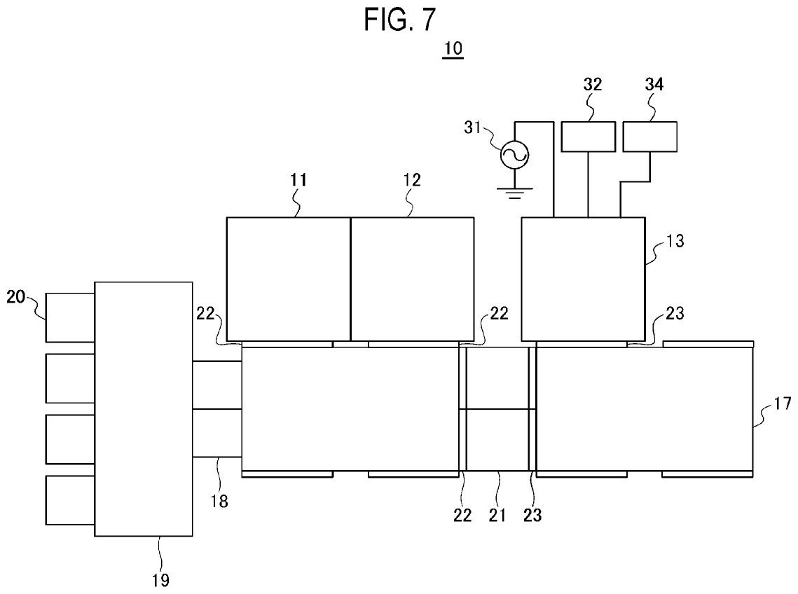

For example, in the semiconductor manufacturing apparatus 10, the formation of the Zr film 27 is performed in the Zr film formation chamber 13, and the etching of the Zr film 27 and the formation of the Ti film 28 are performed in the Ti film formation chamber 14. However, as shown in FIG. 7, by providing the raw material gas source 34 in the Zr film formation chamber 13, the etching of the Zr film 27 and the formation of the Ti film 28 may also be performed in the Zr film formation chamber 13. That is, the Zr film formation chamber 13 may also serve as the Ti film formation chamber 14. In this case, during the formation of the Zr film 27, the film formation gas source 32 supplies a film formation gas into the Zr film formation chamber 13, and during the etching of the Zr film 27 or the formation of the Ti film 28, the raw material gas source 34 supplies the TiCl₄ gas into the Zr film formation chamber 13.

With this configuration, it becomes unnecessary to provide the Ti film formation chamber 14, and it is possible to further reduce a footprint of the semiconductor manufacturing apparatus 10. In addition, since it is possible to eliminate a need to transfer the wafer W to another chamber between the formation of the Zr film 27 and the etching of the Zr film 27, throughput can also be further improved. Further, since the TiCl₄ gas is supplied into the Zr film formation chamber 13 after the formation of the Zr film 27, it is possible to remove Zr adhering to an inner wall of the Zr film formation chamber 13 during the formation of the Zr film 27 by the TiCl₄ gas (see Equation (1) described above). Therefore, it is possible to suppress metal contamination inside the Zr film formation chamber 13.

Further, in the wafer W, the Zr film 27 is formed inside the pattern 26 and the Ti film 28 is formed on the Zr film 27. However, in place of the Zr film 27, a molybdenum (Mo) film or a hafnium (Hf) film may be formed, and the Ti film 28 may be formed on the Mo film or the Hf film. In this case as well, the Mo film or the Hf film is etched by the TiCl₄ gas in the Ti film formation chamber 14.

According to the technique of the present disclosure, in some embodiments, it is possible to suppress an increase in a wiring resistance of a wiring material embedded inside a pattern.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film forming method of forming a metal wiring on a silicon-based substrate to be processed, by forming a contact made of a metal silicide at a bottom portion of a pattern as an opening in an insulating film of the substrate while forming a metal film inside the pattern, the method comprising:
a first film formation process of forming a first metal film inside the pattern;
a film thickness adjustment process of adjusting a film thickness of the formed first metal film; and
a second film formation process of forming a second metal film on the first metal film by using a raw material gas,
wherein in the film thickness adjustment process, the formed first metal film is etched by using the raw material gas.

2. The film forming method of claim 1, wherein the second metal film is stacked on the first metal film by repeating the film thickness adjustment process and the second film formation process.

3. The film forming method of claim 2, wherein the film thickness adjustment process and the second film formation process are repeated by applying a pulsed radio-frequency voltage.

4. The film forming method of claim 1, wherein the second metal film is stacked on the first metal film without repeating the film thickness adjustment process and the second film formation process.

5. The film forming method of claim 1, wherein the raw material gas is not plasmarized in the film thickness adjustment process, and is plasmarized in the second film formation process.

6. The film forming method of claim 1, wherein the raw material gas is plasmarized in any of the film thickness adjustment process and the second film formation process.

7. The film forming method of claim 1, further comprising:
an oxide film removal process of removing an oxide film formed on a surface of the substrate; and
a wiring process of embedding a metal as a wiring material on the second metal film inside the pattern.

8. The film forming method of claim 7, further comprising:
between the second film formation process and the wiring process, a cleaning process of removing etching residues of the first metal film.

9. The film forming method of claim 1, wherein the first metal film includes any one of zirconium, molybdenum, and hafnium.

10. The film forming method of claim 1, wherein the second metal film includes titanium.

11. The film forming method of claim 1, wherein the raw material gas is a titanium-containing chloride gas or a titanium-containing halide gas.

12. The film forming method of claim 11, wherein the raw material gas is a gas further containing at least one of tungsten pentachloride, tungsten hexachloride, molybdenum pentachloride, molybdenum hexachloride, hafnium tetrachloride, or zirconium tetrachloride.

13. The film forming method of claim 1, wherein the pattern is a contact hole or a trench.

14. A semiconductor manufacturing apparatus for forming a metal wiring on a silicon-based substrate to be processed, by forming a contact made of a metal silicide at a bottom portion of a pattern as an opening in an insulating film of the substrate while forming a metal film inside the pattern, the apparatus comprising:
a first film former that forms a first metal film inside the pattern; and
a second film former that forms a second metal film on the formed first metal film by using a raw material gas,
wherein the second film former adjusts a film thickness of the formed first metal film by using the raw material gas.

15. The semiconductor manufacturing apparatus of claim 14, wherein the second film former includes a radio-frequency power supply configured to plasmarize the raw material gas into plasma.

16. The semiconductor manufacturing apparatus of claim 14, wherein the first film former and the second film former are connected to a same vacuum transfer system.

17. The semiconductor manufacturing apparatus of claim 14, wherein the first film former includes an introducer of the raw material gas and serves as the second film former.

18. The semiconductor manufacturing apparatus of claim 14, wherein the second film former performs a cleaning process on the substrate to remove etching residues of the first metal film.
